(19) United States
(12) Patent Application Publication
(10) Pub. No.: US 2014/0061682 A1
(43) Pub. Date: Mar. 6, 2014

(54) SEMICONDUCTOR DEVICE AND METHOD FOR MANUFACTURING SAME

(71) Applicant: KABUSHIKI KAISHA TOSHIBA, Tokyo (JP)

(72) Inventors: Mitsuhiro KOBAYASHI, Kanagawa-ken (JP); Kenichiro ABE, Kanagawa-ken (JP)

(73) Assignee: KABUSHIKI KAISHA TOSHIBA, Tokyo (JP)

(21) Appl. No.: 13/845,262

(22) Filed: Mar. 18, 2013

(30) Foreign Application Priority Data
Aug. 30, 2012 (JP) 2012-190678

(51) Int. Cl. H01L 33/52; H01L 33/08

(52) U.S. Cl. CPC H01L 33/52; H01L 33/08
USPC 257/88; 438/26

(57) ABSTRACT

According to one embodiment, a semiconductor device includes a conductive member, a semiconductor element, a sealing section. The semiconductor element is provided on an upper surface of the conductive member. The sealing section seals part of the conductive member and the semiconductor element. The upper end of the semiconductor element is located above the uppermost portion of the conductive member. The conductive member includes an inclined surface and a lower surface. The inclined surface is provided on an outside of the sealing section and makes an acute angle with the upper surface. The lower surface is provided outside the sealing section and makes an obtuse angle with the inclined surface.

### CROSS-REFERENCE TO RELATED APPLICATIONS

This application is based upon and claims the benefit of priority from the prior Japanese Patent Application No. 2012-190678, filed on Aug. 30, 2012; the entire contents of which are incorporated herein by reference.

### FIELD

Embodiments described herein relate generally to a semiconductor device and a method for manufacturing the same.

### BACKGROUND

With the downsizing of a semiconductor device, the contact area for mounting on a mounting substrate is made small. Thus, it is important to improve the reliability of connection depending on various mounting configurations.

### BRIEF DESCRIPTION OF THE DRAWINGS

FIGS. 1A and 1B are schematic views illustrating a semiconductor device according to a first embodiment;

FIG. 2 is a schematic perspective view illustrating the semiconductor device according to the first embodiment;

FIG. 3 is a schematic perspective view illustrating a semiconductor device according to a reference example;

FIG. 4 is a schematic view illustrating the semiconductor device according to the first embodiment mounted on a mounting substrate;

FIGS. 5A and 5B are schematic views of variations of the semiconductor device according to the first embodiment;

FIG. 6 is a flow chart illustrating a method for manufacturing a semiconductor device according to a second embodiment;

FIGS. 7A to 9C are schematic sectional views illustrating the method for manufacturing a semiconductor device according to the second embodiment;

FIGS. 10A and 10B are schematic views illustrating a semiconductor device according to a third embodiment;

FIG. 11 is a schematic view illustrating the semiconductor device 120 according to the third embodiment;

FIG. 12 is a flow chart illustrating a method for manufacturing a semiconductor device according to a fourth embodiment;

FIGS. 13A to 13C are schematic sectional views illustrating the method for manufacturing a semiconductor device according to the fourth embodiment;

FIGS. 14A and 14B are schematic views illustrating a semiconductor device according to a fifth embodiment;

FIG. 15 is a flow chart illustrating a method for manufacturing a semiconductor device according to a sixth embodiment; and

FIGS. 16A to 19 are schematic sectional views illustrating the method for manufacturing a semiconductor device according to the sixth embodiment.

### DETAILED DESCRIPTION

In general, according to one embodiment, a semiconductor device includes a conductive member, a semiconductor element, a sealing section. The semiconductor element is provided on an upper surface of the conductive member. The sealing section seals part of the conductive member and the semiconductor element. The upper end of the semiconductor element is located above the uppermost portion of the conductive member. The conductive member includes an inclined surface and a lower surface. The inclined surface is provided on an outside of the sealing section and makes an acute angle with the upper surface. The lower surface is provided on an outside of the sealing section and makes an obtuse angle with the inclined surface.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present specification and the drawings, components similar to those described previously with reference to earlier figures are labeled with like reference numerals, and the detailed description thereof is omitted appropriately.

### First Embodiment

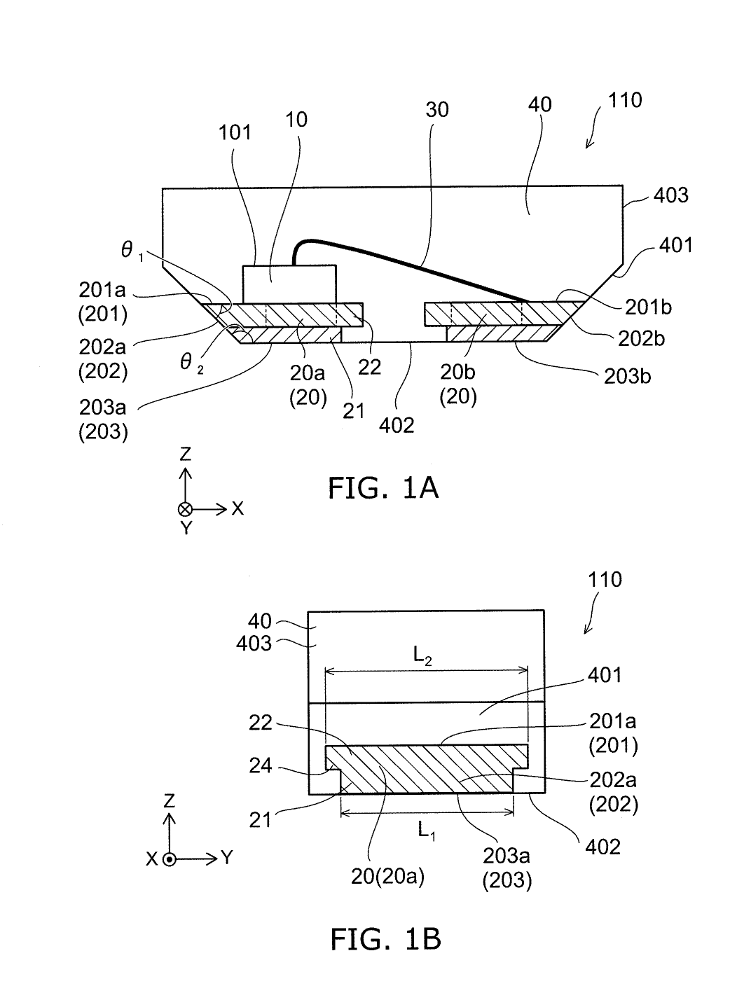

FIGS. 1A and 1B are schematic views illustrating a semiconductor device according to a first embodiment.

More specifically, FIG. 1A is a sectional view of the semiconductor device according to the first embodiment. FIG. 1B is a side view of the semiconductor device according to the first embodiment.

As shown in FIGS. 1A and 1B, the semiconductor device 110 according to the first embodiment includes a conductive member 20, a semiconductor element 10, and a sealing section 40.

The conductive member 20 includes an upper surface 201, an inclined surface 202, and a lower surface 203.

In the following description, the direction normal to the upper surface 201 of the conductive member 20 is referred to as +Z direction. For a member A, the phrase “on A” means “on the +Z direction side of A”. Furthermore, the directions along the upper surface 201 of the conductive member 20 are referred to as +X direction and +Y direction. The “+” direction refers to the direction of the arrow in the figures. The X direction, the Y direction, and the Z direction are orthogonal to each other.

For instance, the conductive member 20 is provided in a plurality. In the first embodiment, the conductive member 20 includes a first conductive member 20a and a second conductive member 20b. In the following, the term “conductive member 20” is meant to include the first conductive member 20a and the second conductive member 20b.

The first conductive member 20a includes a first upper surface 201a, a first inclined surface 202a, and a first lower surface 203a. The second conductive member 20b is spaced in the X direction from the first conductive member. The second conductive member 20b includes a second upper surface 201b, a second inclined surface 202b, and a second lower surface 203b. In the following, the term “upper surface 201” is meant to include the first upper surface 201a and the second upper surface 201b. The term “inclined surface 202” is meant to include the first inclined surface 202a and the second inclined surface 202b. The term “lower surface 203” is meant to include the first lower surface 203a and the second lower surface 203b.

The second conductive member 20b is spaced from the first conductive member 20a in a direction (X direction) along the upper surface 201. For instance, the second conductive member 20b is spaced on the side opposite to the first inclined surface 202a of the first conductive member 20a.

The second inclined surface 202b is a surface on the side opposite to the inclined surface 202a of the first conductive member 20a. This suppresses that the fillet of the solder formed on one inclined surface 202 is brought into contact with the other inclined surface 202 when the semiconductor device 110 is mounted on a mounting substrate. That is, short circuit between the first conductive member 20a and the second conductive member 20b is suppressed.

In the first embodiment, the conductive member 20 is provided integrally from the upper surface 201 to the lower surface 203. In other words, no member other than the conductive member 20 is interposed between the upper surface 201 and the lower surface 203. The lower surface 203 of the conductive member 20 is a surface on the opposite side from the upper surface 201. For instance, the conductive member 20 is made of metal. The plurality of conductive members 20 are formed by etching a flat lead frame made of metal. Thus, the first lower surface 203a and the second lower surface 203b are provided on the same plane. Accordingly, at the time of mounting, the semiconductor device 110 is stably mounted on a mounting substrate. Furthermore, because the conductive members 20 are formed from one lead frame, the semiconductor device 110 is thinned.

The semiconductor element 10 is provided on e.g. the first upper surface 201a. The semiconductor element 10 includes an upper end 101. For instance, the surface of the semiconductor element 10 opposite from the upper end 101 is connected to the first conductive member 20a through a die mounting material (not shown). Thus, heat generated from the semiconductor element 10 is transferred from immediately below the conductive member 20 to the mounting substrate and released.

On the other hand, part of the upper end 101 of the semiconductor element 10 is connected to the second conductive member 20b through a bonding wire 30. Such a package is called DFN (dual flat non-leaded) package.

The semiconductor element 10 is e.g. a light emitting element. The light emitted from the semiconductor element 10 is emitted outside from at least the upper end 101. Specifically, the semiconductor element 10 is e.g. an LED (light emitting diode).

The sealing section 40 seals part of the conductive member 20, and the semiconductor element 10. In the first embodiment, the sealing section 40 covers the upper surface 201 of the conductive member 20, the semiconductor element 10, and the bonding wire 30. In the case where the semiconductor element 10 is a light emitting element, the sealing section 40 is translucent in e.g. the wavelength region of the emission light of this light emitting element. The sealing section 40 includes e.g. silicone resin.

Furthermore, the sealing section 40 may include phosphor excited by the emission light of the light emitting element. Thus, light having a wavelength region wider than the emission wavelength range of the light emitting element is emitted outside from the semiconductor device 110.

The upper end 101 of the semiconductor element 10 is located above the uppermost portion of the conductive member 20. Here, the “uppermost portion of the conductive member 20” refers to the portion located on the normal direction (+Z direction) side of the uppermost surface 201 of the conductive member 20. In the first embodiment, the upper surface 201 of the conductive member 20 extends to the end portion of the sealing section 40. The first upper surface 201a and the second upper surface 201b are formed on the same plane. Thus, the “uppermost portion of the conductive member 20” in the first embodiment is the upper surface 201. In other words, in the first embodiment, for instance, the upper end 101 of the semiconductor element 10 is located above the upper surface 201 of the conductive member 20.

In the case where the conductive member 20 includes a protrusion (not shown) protruding from the upper surface 201 to the +Z direction side, the “uppermost portion of the conductive member 20” is this protrusion. Also in this case, preferably, the upper end 101 of the semiconductor element 10 is located above this protrusion.

In the case where the semiconductor element 10 is a light emitting element, preferably, the portion of the semiconductor element 10 occupying half or more in the −Z direction from the upper end 101 is located above the upper surface 201. More preferably, the entire portion of the semiconductor element 10 is located above the upper surface 201. Thus, the light emitted outside from the semiconductor element 10 is emitted to the outside of the semiconductor device 110 without being blocked by the conductive member 20.

The inclined surface 202 is provided on the outside of the sealing section 40. In other words, the inclined surface 202 is exposed from the sealing section 40. The lower surface 203 is also provided on the outside of the sealing section 40. In other words, the lower surface 203 is exposed from the sealing section 40.

For instance, the continuous region of the first conductive member 20a from the first inclined surface 202a to the first lower surface 203a is exposed without the intermediary of the sealing section 40. The same also applies to the second conductive member 20b. Thus, when the semiconductor device 110 is mounted on a mounting substrate through a solder, the solder runs off from the lower surface 203, and a fillet of the solder is formed on the inclined surface 202.

On the surface of the inclined surface 202 and the lower surface 203, the same plating layer may be provided. This improves solder wettability at the time of mounting.

The angle θ₁ between the inclined surface 202 and the upper surface 201 is an acute angle. In the case where there is a bent surface (not shown) or unevenness (not shown) between the inclined surface 202 and the upper surface 201, the angle θ₁ refers to the angle between the extended surface of the inclined surface 202 and the extended surface of the upper surface 201.

Specifically, the angle θ₁ is preferably 30 degrees or more. Thus, when the semiconductor device 110 is mounted on a mounting substrate through a solder, the connection of solder can be verified from outside.

Furthermore, the angle θ₁ is preferably 60 degrees or less. Thus, half or more of the solder fillet formed on the inclined surface 202 is formed inside the outline of the semiconductor device 110 as viewed in the Z direction. That is, the solder fillet does not excessively expand the formation region of the semiconductor device 110 on the mounting substrate.

The angle θ₂ between the lower surface 203 and the inclined surface 202 is an obtuse angle. In the case where there is a bent surface (not shown) or unevenness (not shown) between the lower surface 203 and the inclined surface 202, the angle θ₂ refers to the angle between the extended surface of the lower surface 203 and the extended surface of the inclined surface 202.

In the first embodiment, as described above, the lower surface 203 of the conductive member 20 is a surface on the opposite side from the upper surface 201. Thus, if the angle θ₁ is an acute angle, the angle θ₂ is definitely an obtuse angle.

In the first embodiment, as viewed in the Z direction, the end portion in the X direction of the conductive member 20 is located inside the end portion in the X direction of the sealing section 40. This suppresses that the solder formation region at the time of mounting spreads outside the outline of the semiconductor device 110.

As shown in FIG. 1B, the conductive member 20 includes a protrusion 24. The protrusion 24 protrudes to a first direction (e.g., Y direction) along the upper surface 201. The protrusion 24 is surrounded with the sealing section 40. In other words, the sealing section 40 extends around the protrusion 24 from the upper surface 201 side. Thus, the sealing section 40 is locked on the protrusion 24.

For instance, the conductive member 20 may include a first portion 21 and a second portion 22 at different positions in the Z direction. The first portion 21 includes a lower surface 203. The first portion 21 has a first length L₁ in the first direction (the aforementioned Y direction). The second portion 22 is provided on the first portion 21 and includes an upper surface 201. The second portion 22 has a second length L₂ longer than the first length L₁ in the first direction (the aforementioned Y direction). Thus, the second portion 22 protrudes from the first portion 21. In this case, the protrusion 24 is part of the second portion 22 in which the second portion 22 protrudes from the first portion 21.

For instance, the area of the upper surface 201 of the conductive member 20 is larger than the area of the lower surface 203. Thus, a protrusion 24 is provided in the lateral region of the conductive member 20 except the inclined surface 202.

For instance, the conductive member 20 is formed by half etching. Thus, a protrusion 24 is formed at the center position in the Z direction of the conductive member 20.

The conductive member 20 is not necessarily needed to be centrosymmetric as viewed in the X direction. For instance, the protrusion 24 may be provided on one side in the Y direction of the conductive member 20. The above protrusion 24 may not be provided.

The sealing section 40 extends beyond the first portion 21 to the second portion 22 in the Y direction. Thus, the sealing section 40 extends around the protrusion 24, and is locked by the first portion 21. This suppresses detachment of the sealing section 40 from the conductive member 20 due to the difference between the thermal expansion coefficient of the sealing section 40 and the thermal expansion coefficient of the conductive member 20 when, for instance, the semiconductor device 110 is mounted on a mounting substrate.

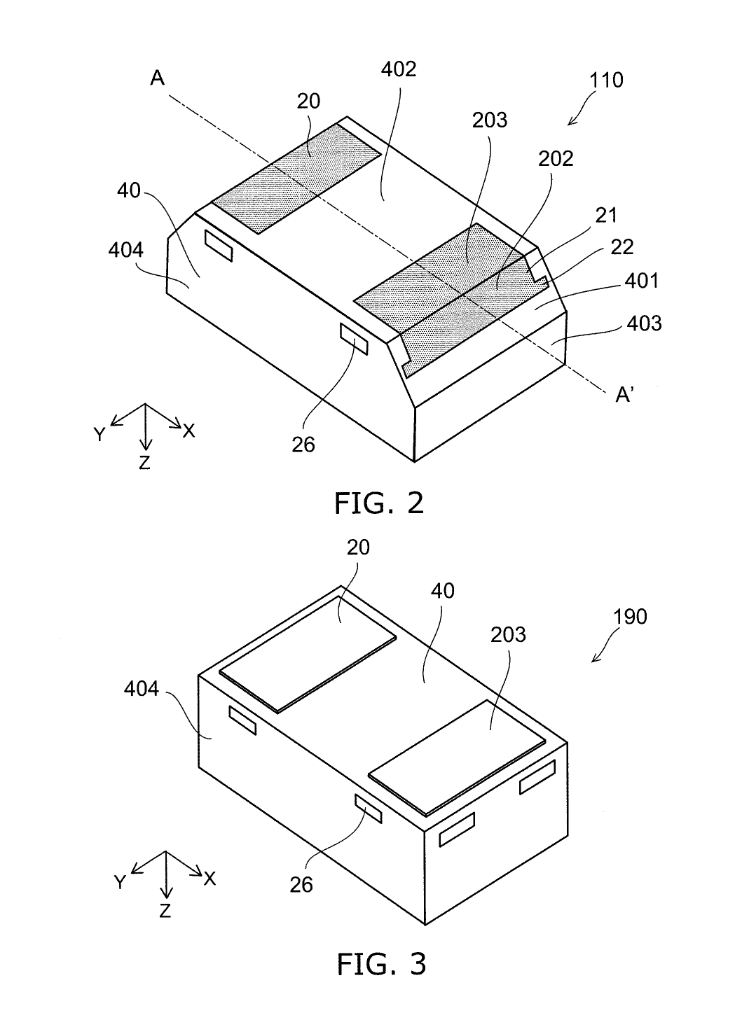

FIG. 2 is a schematic perspective view illustrating the semiconductor device according to the first embodiment.

FIG. 2 shows the semiconductor device 110 as viewed from the −Z direction.

As shown in FIG. 2, the continuous region of the conductive member 20 from the inclined surface 202 to the lower surface 203 is exposed without the intermediary of the sealing section 40.

The sealing section 40 includes a first surface 401 flush with the inclined surface 202. In other words, the first surface 401 of the sealing section 40 does not protrude from the inclined surface 202. Thus, when the semiconductor device 110 is mounted on a mounting substrate through a solder, the connection of solder can be easily verified from e.g. the direction along the first surface 401.

The inclined surface 202 of the conductive member 20 is provided up to the portion in contact with the sealing section 40 in the Y direction. This expands the range in which the fillet of the solder is formed. Thus, the fixation strength of the semiconductor device 110 is improved.

The sealing section 40 includes a second surface 402 flush with the lower surface 203. In other words, the second surface 402 of the sealing section 40 does not protrude from the lower surface 203. Thus, when the semiconductor device 110 is mounted on a mounting substrate through a solder, the sealing section 40 does not hinder connection between the lower surface 203 and the mounting substrate. That is, the lower surface 203 of the semiconductor device 110 is stably fixed to the mounting substrate through a solder.

For instance, the side surface of the sealing section 40 at which the inclined surface 202 is not exposed (side surface 403 and side surface 404) is provided perpendicular to the lower surface 203. The suspension lead portion 26 of the conductive member 20 may be exposed from the side surface 404. On this suspension lead portion 26, solder is not formed.

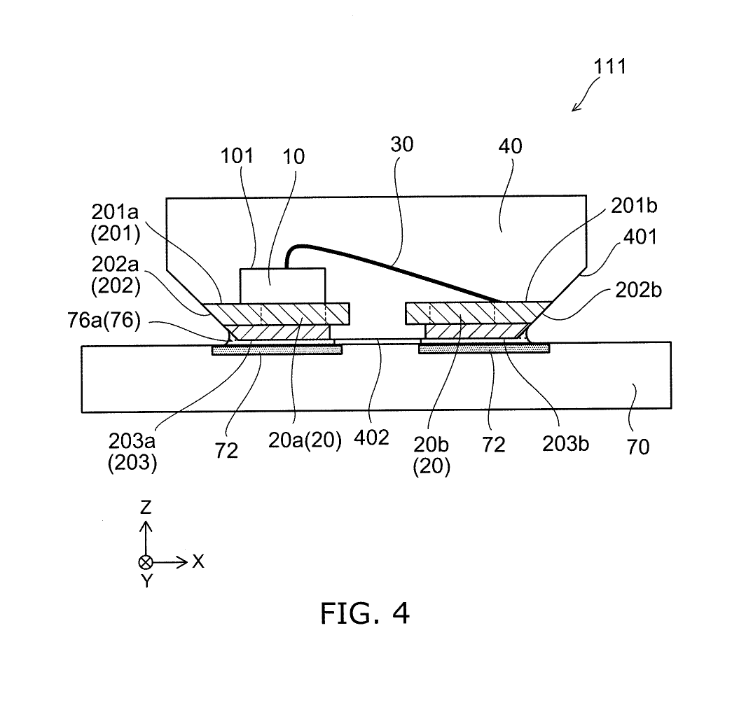

Next, with reference to FIGS. 3 and 4, the effect of the first embodiment is described.

FIG. 3 is a schematic perspective view illustrating a semiconductor device according to a reference example.

FIG. 4 is a schematic view illustrating the semiconductor device according to the first embodiment mounted on a mounting substrate.

FIG. 3 is a schematic perspective view illustrating a semiconductor device 190 according to a first reference example.

As shown in FIG. 3, the sealing configuration of the semiconductor device 190 according to the first reference example is e.g. what is called DFN, CSP (chip scale package), or WLP (wafer level package).

In the first reference example, the lower surface 203 is exposed from the sealing section 40. The side surface 404 of the sealing section 40 is formed perpendicular to the lower surface 203. The inclined surface 202 is not formed. Although the suspension lead portion 26 is exposed as in the first embodiment, it does not contribute to connection to a mounting substrate. The suspension lead portion 26 refers to the portion linking a plurality of conductive members 20 during the manufacturing process.

In the first reference example, when the semiconductor device 190 is mounted on a mounting substrate through a solder, the solder is in contact with only the lower surface 203. In the first reference example, it is difficult to verify the connection of solder after the mounting.

Furthermore, due to e.g. warpage of the mounting substrate 70, a stress may be applied to the semiconductor device 190 in the X direction. In the first reference example, the semiconductor device 190 may be detached by such a stress applied to the semiconductor device 190 in the X direction.

In contrast, the semiconductor device 110 according to the first embodiment is mounted on the mounting substrate 70 as follows, for instance.

As shown in FIG. 4, an electronic component 111 includes the semiconductor device 110 and the mounting substrate 70. This electronic component 111 is also one aspect of the first embodiment.

At the upper end of the mounting substrate 70, a plurality of connecting sections 72 for mounting the semiconductor device 110 are provided. The connecting section 72 is what is called a land pattern for connecting the semiconductor device 110. In the state in which the semiconductor device 110 is mounted on the mounting substrate 70, each of the plurality of connecting sections 72 is provided at the position overlapping the first conductive member 20a or the second conductive member 20b as viewed in the Z direction. The mounting substrate 70 is e.g. a printed wiring substrate. Although not shown, the mounting substrate 70 may include a wiring connected to the connecting section 72. For instance, another semiconductor device for driving the semiconductor device 110 may be mounted on the mounting substrate 70, and this wiring may connect the semiconductor device 110 and the other semiconductor device.

As described above, the continuous region of the first conductive member 20a from the first inclined surface 202a to the first lower surface 203a is exposed without the intermediary of the sealing section 40. The same also applies to the second conductive member 20b. Furthermore, the angle between the inclined surface 202 and the upper surface 201 (θ₁ shown in FIG. 1A) is an acute angle. When the semiconductor device 110 is mounted on the mounting substrate 70 through a solder 76, the solder 76 runs off from the lower surface 203. The fillet 76a of the solder 76 is formed on the inclined surface 202. Thus, the connection of the solder 76 can be verified from outside.

Furthermore, the solder 76 is formed not only on the lower surface 203 but also on the inclined surface 202. Within the limited planar area of the connecting section 72, the contact area of the conductive member 20 being in contact with the solder 76 is expanded. Thus, the fixation strength of the semiconductor device 110 to the mounting substrate 70 is improved. The fixation strength is ensured even if the semiconductor device 110 is downsized.

Furthermore, for the stress applied to the semiconductor device 110 in the X direction, the semiconductor device 110 is locked on the mounting substrate 70 by the fillet 76a of the solder 76. This suppresses detachment of the semiconductor device 110 from the mounting substrate 70.

### (Variations)

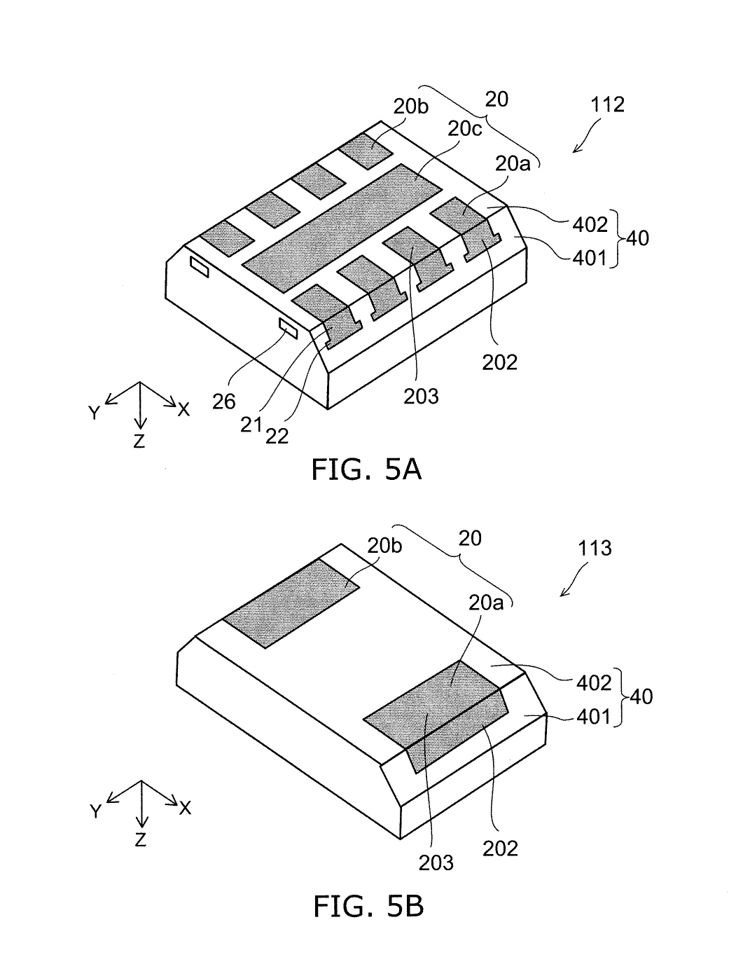

Next, with reference to FIGS. 5A and 5B, variations of the first embodiment are described.

FIGS. 5A and 5B are schematic views of variations of the semiconductor device according to the first embodiment.

As shown in FIG. 5A, in a first variation according to the first embodiment, for instance, more than two conductive members 20 are provided. The semiconductor device 112 includes a first conductive member 20a, a second conductive member 20b, and a third conductive member 20c. Of the plurality of conductive members 20, the third conductive member 20c is provided at the center as viewed in the Z direction. The third conductive member 20c is what is called a die pad. On the side opposite to the lower surface 203 of the third conductive member 20c, the semiconductor element 10 is provided.

The first conductive member 20a is provided in a plurality. The second conductive member 20b is provided in a plurality. For instance, the plurality of first conductive members 20a and the plurality of second conductive members 20b are equally spaced in the Y direction of the third conductive member 20c. To the semiconductor element, a plurality of bonding wires are connected. The semiconductor element is connected to the first conductive member 20a or the second conductive member 20b through the plurality of bonding wires. Each of the plurality of first conductive members 20a includes a first portion 21 and a second portion 22. Thus, the sealing section 40 is locked by a plurality of first portions 21.

On the third conductive member 20c, a plurality of semiconductor elements may be provided. Furthermore, also in the +Y direction and the −Y direction of the third conductive member 20c, a conductive member including an inclined surface 202 may be provided.

As in the first variation according to the first embodiment, a plurality of conductive members 20 may be placed at arbitrary positions.

As shown in FIG. 5B, in a second variation according to the first embodiment, for instance, the semiconductor device 113 is a CSP or WLP. In this case, the mounting substrate is an interposer. The conductive member 20 is e.g. a through via of the interposer. Here, the insulating base material portion of the interposer is also inclusively denoted as the sealing section 40. At the side surface of the sealing section 40, suspension leads and the like are not exposed.

In the second variation according to the first embodiment, the interposer and the sealing section 40 are obliquely cut. Accordingly, the conductive member 20 being a through via is provided with an inclined surface 202. Thus, also in package configurations other than DFN, the inclined surface 202 may be provided.

### Second Embodiment

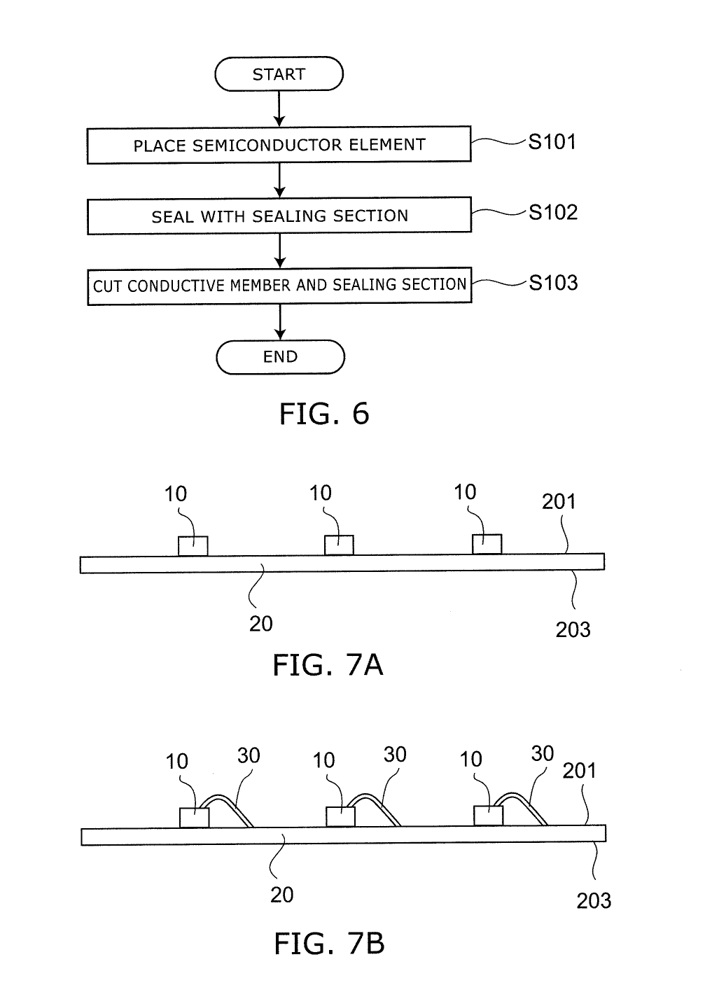

FIG. 6 is a flow chart illustrating a method for manufacturing a semiconductor device according to a second embodiment.

As shown in FIG. 6, the method for manufacturing a semiconductor device according to this embodiment includes placing a semiconductor element (step S101), sealing with a sealing section (step S102), and cutting the conductive member and the sealing section (step S103). In the following, an example of each step is described.

First, in the placing of a semiconductor element shown in step S101, a semiconductor element 10 is placed on the upper surface 201 of a conductive member 20.

Next, in the sealing with a sealing section shown in step S102, the region of the conductive member 20 other than the lower surface 203 on the side opposite to the upper surface 201, and the semiconductor element 10 are sealed with a sealing section 40.

Next, in the cutting of the conductive member and the sealing section shown in step S103, the conductive member 20 and the sealing section 40 are cut from the lower surface 203 side. Thus, an inclined surface 202 exposed from the sealing section 40 is formed. In the inclined surface 202, the angle θ₁ with respect to the tangential direction of the upper surface 201 is an acute angle.

By the process shown in the above steps S101-S103, the inclined surface 202 can be formed up to the end portion of the conductive member 20 without preparing a conductive member 20 having a complex shape.

Next, with reference to FIGS. 7A to 9C, a more detailed example of the method for manufacturing a semiconductor device according to the second embodiment is described.

FIGS. 7A to 9C are schematic sectional views illustrating the method for manufacturing a semiconductor device according to the second embodiment.

First, the placing of a semiconductor element (step S101) is performed.

As shown in FIG. 7A, a conductive member 20 is prepared. The conductive member 20 is e.g. a metallic lead frame. In the conductive member 20, for instance, a first conductive member 20a, a second conductive member 20b, and a suspension lead portion 26 linking them are formed by e.g. etching. Here, by half etching, a first portion 21 and a second portion 22 are formed in the conductive member 20. At this stage, an inclined surface 202 described later may not be formed in the conductive member 20.

In FIG. 7A, these portions are not shown.

On the upper surface 201 of the conductive member 20, a semiconductor element 10 is placed through a die mounting material (not shown). Depending on the die mounting material, heat treatment may be performed. In the case where the semiconductor element 10 is a light emitting element, the semiconductor element 10 is placed so that, for instance, the upper end 101 for emitting light is directed to the direction normal to the upper surface 201.

Next, as shown in FIG. 7B, by e.g. ultrasonic bonding, one end of a bonding wire 30 is connected to the semiconductor element 10, and the other end is connected to the conductive member 20.

Next, the sealing with a sealing section (step S102) is performed.

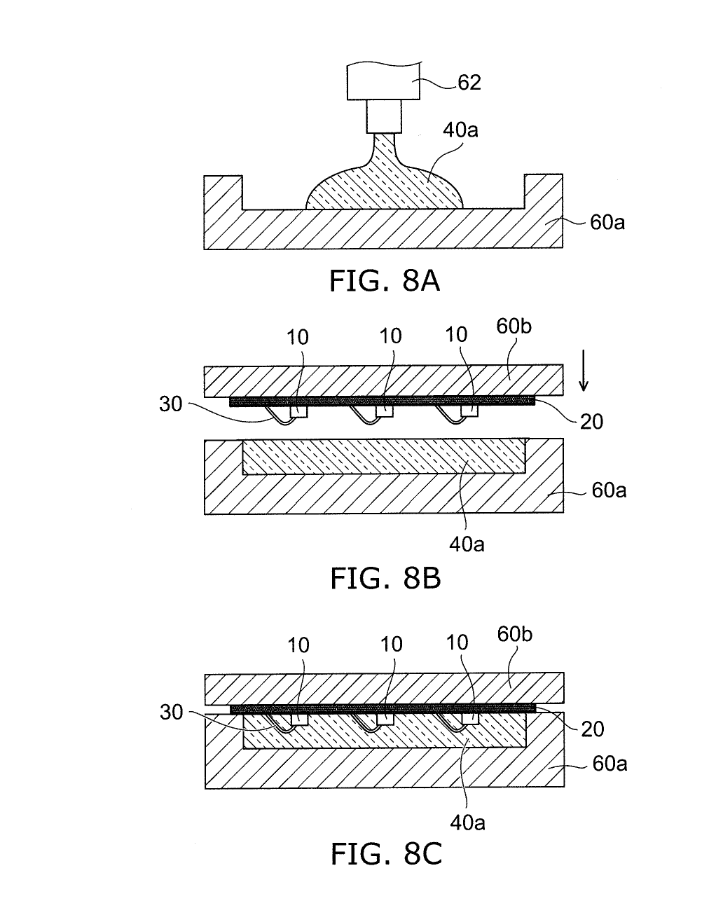

As shown in FIG. 8A, a mold 60a is prepared. At the upper end of the mold 60a, a recess (with no reference numeral) shaped like e.g. a rectangular solid is formed. By a dispenser 62, a sealing resin 40a is supplied into the mold 60a. The sealing resin 40a is e.g. a transparent silicone resin. Here, the sealing resin 40a may include phosphor.

Next, as shown in FIG. 8B, a support film 60b is attached in contact with the lower surface 203 of the conductive member 20. Thus, the sealing section 40 is not formed on the lower surface 203 of the conductive member 20.

Next, as shown in FIG. 8C, with the light emitting element 10 directed to the mold 60a side, the conductive member 20 is pressed to the mold 60a. Here, the sealing resin 40a covers the semiconductor element 10, the bonding wire 30, and the upper surface 201 of the conductive member 20. The sealing resin 40a also penetrates into the portion of the conductive member 20 removed by the aforementioned etching.

Next, with the upper surface 201 side of the conductive member 20 pressed to the sealing resin 40a, heat treatment (mold cure) is performed. Thus, the sealing resin 40a is cured to form a sealing section 40.

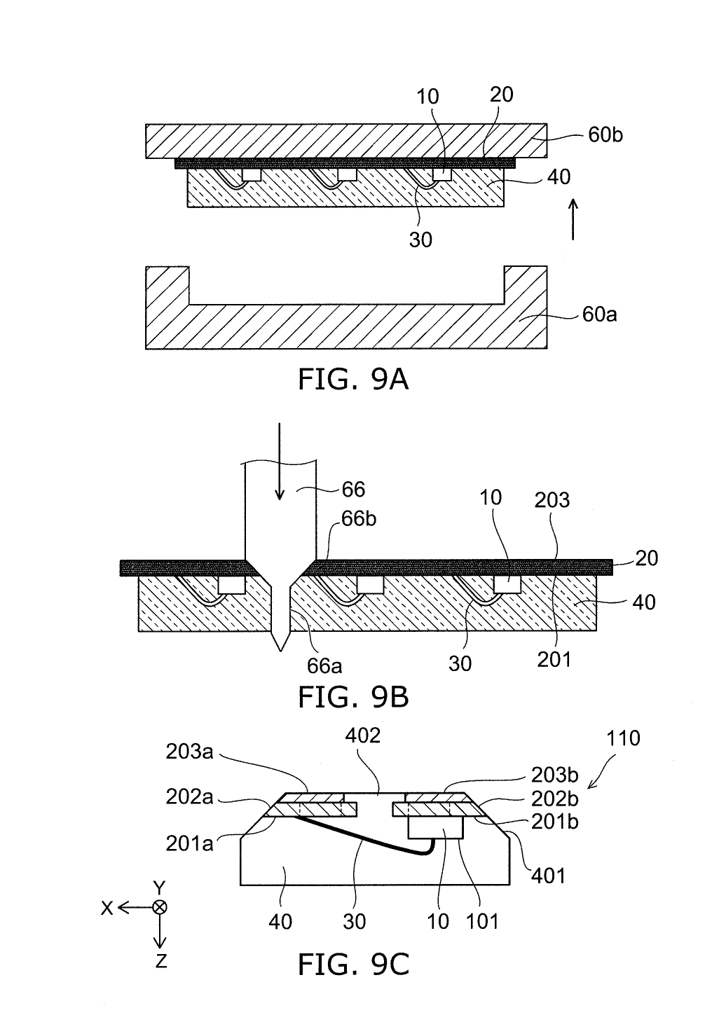

Next, as shown in FIG. 9A, the conductive member 20 provided with the cured sealing section 40 is pulled away from the mold 60a. Thus, the region of the conductive member 20 other than the lower surface 203 on the side opposite to the upper surface 201, and the semiconductor element 10 are sealed with a sealing section 40. At this stage, the support film 60b may be stripped away.

Next, the cutting of the conductive member and the sealing section (step S103) is performed.

As shown in FIG. 9B, a blade 66 is prepared. The blade 66 is a circular thin blade. The blade 66 includes e.g. a first cutting portion 66a for cutting the sealing section 40, and a second cutting portion 66b for forming an inclined surface 202. The first cutting portion 66a is provided in the direction perpendicular to the rotation axis of the blade 66. The angle between the second cutting portion 66b and the first cutting portion 66a is an obtuse angle.

The blade 66 is used to cut the conductive member 20 and the sealing section 40 from the lower surface 203 side of the conductive member 20. Here, the second cutting portion 66b cuts part of the conductive member 20. Thus, an inclined surface 202 exposed from the sealing section 40 is formed. In the inclined surface 202, the angle θ₁ with respect to the tangential direction of the upper surface 201 is an acute angle.

Although not shown, step S103 may be performed in the state in which the aforementioned support film 60b is attached. Alternatively, this step may be performed after a support film 60b is attached again in contact with the lower surface 203 of the conductive member 20.

After cutting the conductive member and the sealing section, the lower surface 203 and the inclined surface 202 of the conductive member 20 may be plated.

As shown in FIG. 9C, a semiconductor device 110 is formed. The upper end 101 of the semiconductor element 10 is located on the +Z direction side of the position of the conductive member 20 remotest from the upper surface 201 in the direction normal to the upper surface 201. The conductive member 20 includes an inclined surface 202 and a lower surface 203. The inclined surface 202 is exposed from the sealing section 40 and makes an acute angle with the upper surface 201. The lower surface 203 is exposed from the sealing section 40 and makes an obtuse angle with the inclined surface 202.

Next, the effect of the second embodiment is described.

In the second embodiment, in the cutting of the conductive member and the sealing section (step S103), the inclined surface 202 of the conductive member 20 is formed. Thus, before the sealing with a sealing section (step S102), there is no need to prepare a conductive member 20 having a complex shape. Furthermore, the inclined surface 202 is formed with no sealing section 40 attached thereto.

Furthermore, in the cutting of the conductive member and the sealing section (step S103), the blade 66 including the second cutting portion 66b is used. Thus, existing facilities can be used except for using the blade 66. Thus, the semiconductor device 110 is formed without decreasing the productivity.

### Third Embodiment

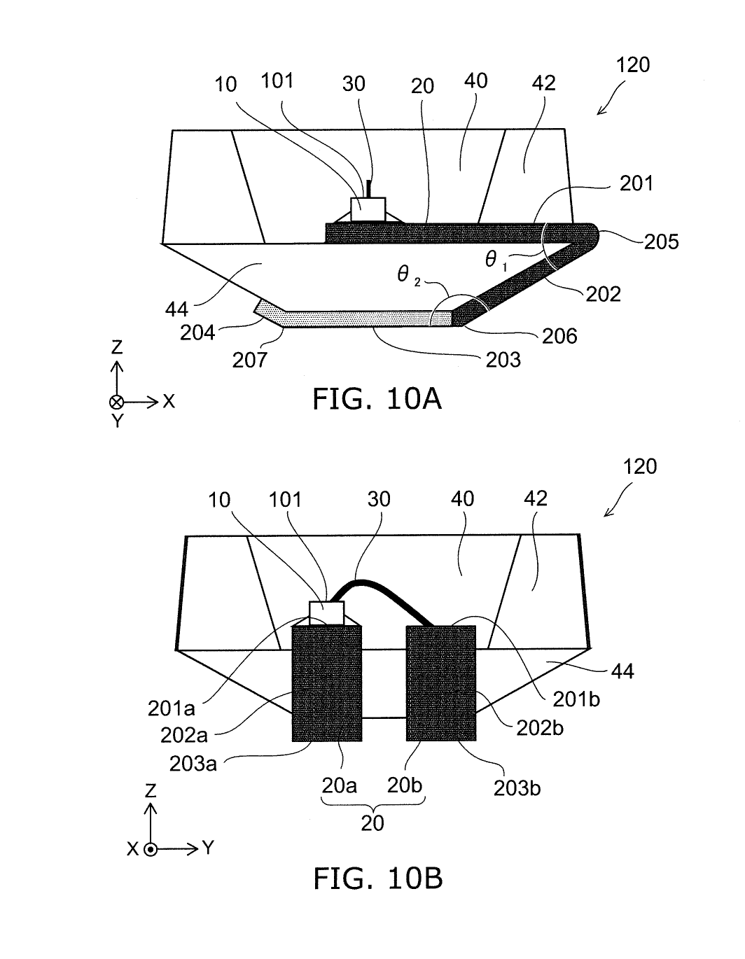

FIGS. 10A and 10B are schematic views illustrating a semiconductor device according to a third embodiment.

More specifically, FIG. 10A is a sectional view of the semiconductor device 120 according to the third embodiment.

FIG. 10B shows the semiconductor device 120 according to the third embodiment as viewed from the inclined surface 202 side.

The semiconductor device 120 according to the third embodiment is different from the semiconductor device 110 according to the first embodiment in the shape of the conductive member 20.

As shown in FIG. 10A, the semiconductor device 120 according to the third embodiment includes a conductive member 20, a semiconductor element 10, a sealing section 40, a housing case 42, and a base section 44. For instance, the semiconductor element 10 is a light emitting element.

The housing case 42 is provided on the upper surface 201 of the conductive member 20. The housing case 42 includes e.g. an opening (with no reference numeral) at the center. Inside the opening of the housing case 42, the semiconductor element 10 is placed. In other words, the housing case 42 is provided so as to surround the semiconductor element 10 as viewed in the Z direction. Furthermore, the sealing section 40 is provided inside this opening.

The base section 44 is shaped like e.g. a pyramid. The upper portion of the base section 44 is in contact with the surface on the side opposite to the upper surface 201 of the conductive member 20.

Either or both of the housing case 42 and the base section 44 may be formed integrally from the same material as the sealing section 40. In the case where the semiconductor element 10 is a light emitting element, preferably, at least the sealing section 40 and the housing case 42 are translucent in the wavelength range of the emission light of this light emitting element.

The conductive member 20 is bent to the side opposite to the upper surface 201 provided with the semiconductor element 10. The conductive member 20 includes an inclined surface 202 and a lower surface 203. The conductive member 20 may further include an inclined surface 204 on the side opposite to the inclined surface 202 of the lower surface 203.

The conductive member 20 includes a bent surface 205 provided between the upper surface 201 and the inclined surface 202, and a bent surface 206 provided between the inclined surface 202 and the lower surface 203. A bent surface 207 may be provided between the lower surface 203 and the inclined surface 204.

The angle θ₁ between the inclined surface 202 and the upper surface 201 is an acute angle. The angle θ₂ between the lower surface 203 and the inclined surface 202 is an obtuse angle. As described above, the angle θ₁ refers to the angle between the extended surface of the inclined surface 202 and the extended surface of the upper surface 201. The angle θ₂ refers to the angle between the extended surface of the lower surface 203 and the extended surface of the inclined surface 202.

Between the upper surface 201 and the lower surface 203, for instance, the base section 44 is interposed. The surfaces of the conductive member 20 on the side opposite to the inclined surface 202 and on the side opposite to the lower surface 203 are in contact with the base section 44.

The angle between the upper surface 201 and the inclined surface 202 is an acute angle. In the case where the semiconductor element 10 is a light emitting element, this angle is adapted to the desired light emitting direction.

As shown in FIG. 10B, the conductive member 20 is provided in a plurality. The conductive member 20 includes a first conductive member 20a and a second conductive member 20b. The first conductive member 20a includes a first upper surface 201a, a first inclined surface 202a, and a first lower surface 203a. The second conductive member 20b includes a second upper surface 201b, a second inclined surface 202b, and a second lower surface 203b.

The second conductive member 20b is spaced in the Y direction from the first conductive member 20a. The first conductive member 20a and the second conductive member 20b are exposed from the sealing section 40 with respect to the same Y direction.

The second inclined surface 202b is juxtaposed on the same side as the side of the first conductive member 20a provided with the first inclined surface 202a. The first inclined surface 202a and the second inclined surface 202b are provided along the same outer surface of the sealing section 40. The term “outer surface of the sealing section 40” used herein refers to e.g. the side surface of the base section 44. For instance, the first inclined surface 202a and the second inclined surface 202b are provided on the same plane. Thus, the first inclined surface 202a and the second inclined surface 202b are connected to a mounting substrate through a solder. That is, the semiconductor device 120 can be mounted on the mounting substrate in a tilted manner.

The second lower surface 203b is provided on the same side as the side of the first conductive member 20a provided with the first lower surface 203a. For instance, the first lower surface 203a and the second lower surface 203b are provided on the same plane.

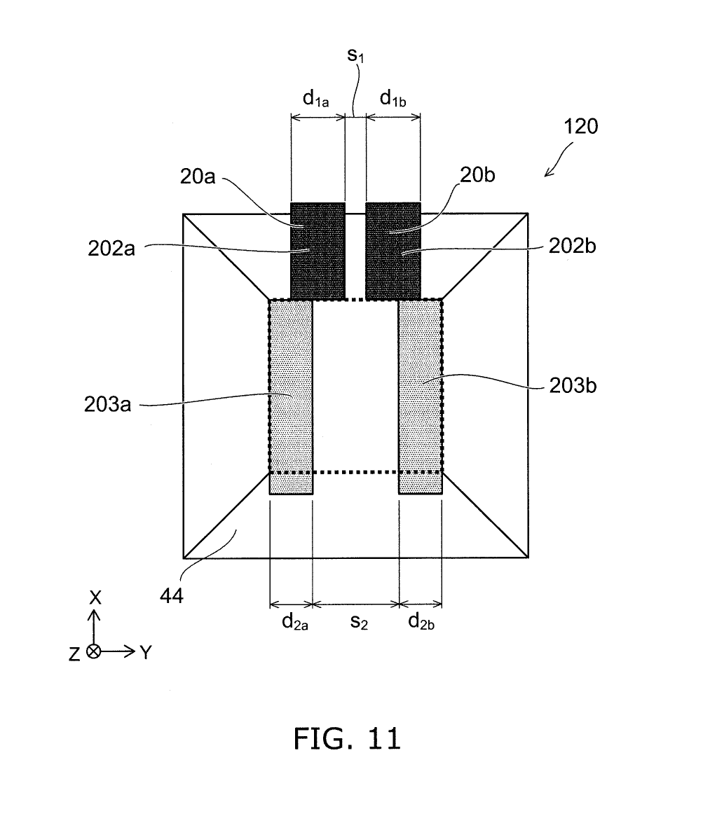

FIG. 11 is a schematic view illustrating the semiconductor device 120 according to the third embodiment.

FIG. 11 shows the semiconductor device 120 according to the third embodiment as viewed from the lower surface 203 side.

As shown in FIG. 11, the semiconductor element 10 is provided on e.g. the first upper surface 201a. The semiconductor element 10 is connected to the first conductive member 20a through a die mounting material (not shown). On the other hand, part of the upper end 101 of the semiconductor element 10 is connected to the second conductive member 20b through a bonding wire 30.

The width (d₁ₐ and d_{1b}) of the inclined surface 202 in the second direction (Y direction) from the first conductive member 20a toward the second conductive member 20b is wider than the width (d₂ₐ and d_{2b}) of the lower surface 203 in the Y direction. Thus, as in the fifth embodiment described later, the semiconductor device 120 can be mounted on the mounting substrate in a tilted manner by transferring the connection state of the semiconductor device 120 by solder stress. Preferably, the width d₁ₐ of the first inclined surface 202a and the width d_{1b} of the second inclined surface 202b are equal.

The distance s₁ between the first inclined surface 202a and the second inclined surface 202b is narrower than the distance s₂ between the first lower surface 203a and the second lower surface 203b. The first inclined surface 202a and the first lower surface 203a are shifted from each other as viewed in the Z direction. The second inclined surface 202b and the second lower surface 203b are shifted from each other in the direction opposite to the shifted direction of the first inclined surface 202a and the first lower surface 203a. Thus, before the aforementioned transfer of the connection state, the semiconductor device 120 can be temporarily connected to the mounting substrate.

Preferably, the portion in which the inclined surface 202 and the lower surface 203 are shifted from each other as viewed in the Z direction overlaps the bent portion (dotted portion) of the base section 44 shaped like a pyramid.

Also in the third embodiment, as in the first embodiment, the fillet of the solder can be verified from outside. Furthermore, in the third embodiment, as in the fifth embodiment described later, the semiconductor device 120 can be mounted on the mounting substrate in a tilted manner.

### Fourth Embodiment

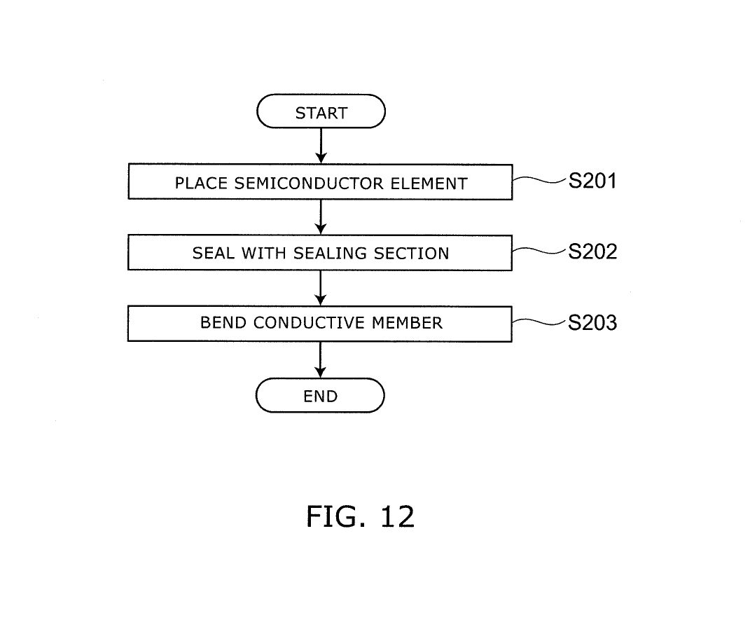

FIG. 12 is a flow chart illustrating a method for manufacturing a semiconductor device according to a fourth embodiment.

As shown in FIG. 12, the method for manufacturing a semiconductor device according to this embodiment includes placing a semiconductor element (step S201), sealing with a sealing section (step S202), and bending the conductive member (step S203). In the following, an example of each step is described.

First, in the placing of a semiconductor element shown in step S201, a semiconductor element 10 is placed on the upper surface 201 of a conductive member 20.

Next, in the sealing with a sealing section shown in step S202, part of the conductive member 20 and the semiconductor element 10 are sealed with a sealing section 40.

Next, in the bending of the conductive member shown in step S203, the portion of the conductive member 20 exposed from the sealing section 40 is bent to the side opposite to the upper surface 201 of the conductive member 20. Thus, an inclined surface 202 making an acute angle with the upper surface 201, and a lower surface 203 making an obtuse angle with the inclined surface 202 are formed.

Also by the process shown in the above steps S201-S203, the inclined surface 202 can be formed up to the end portion of the conductive member 20 without preparing a conductive member 20 having a complex shape.

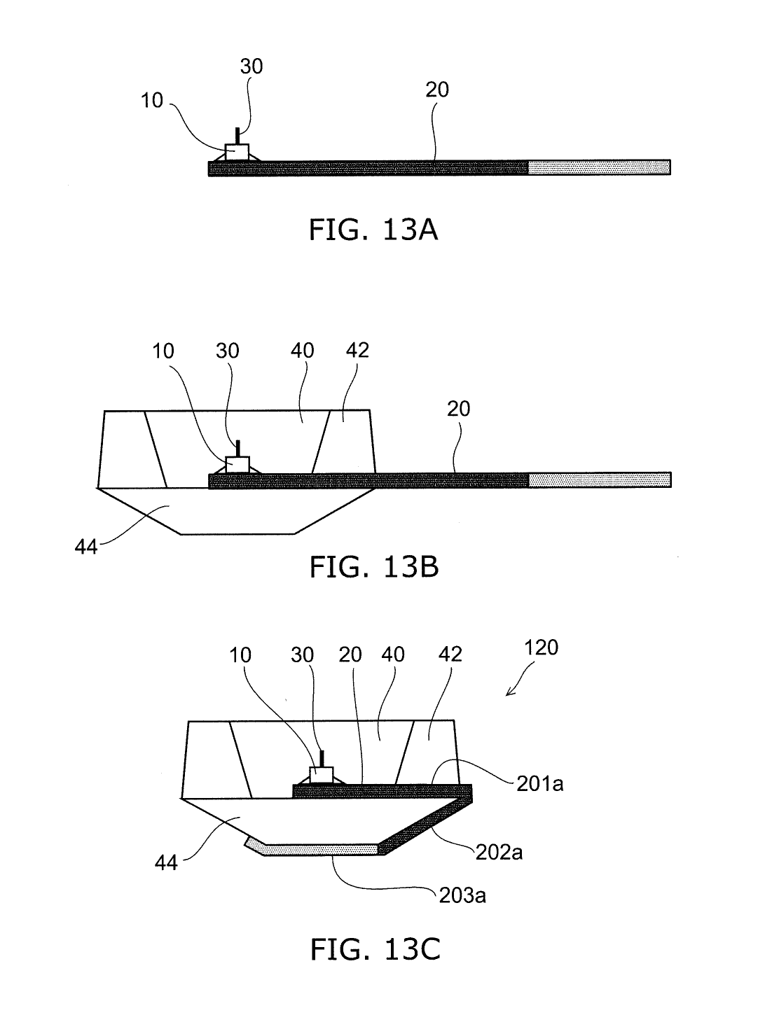

Next, with reference to FIGS. 13A to 13C, a more detailed example of the method for manufacturing a semiconductor device according to the fourth embodiment is described.

FIGS. 13A to 13C are schematic sectional views illustrating the method for manufacturing a semiconductor device according to the fourth embodiment.

First, the placing of a semiconductor element (step S201) is performed.

As shown in FIG. 13A, a conductive member 20 is prepared. The conductive member 20 is e.g. a metallic lead frame. In the conductive member 20, for instance, a first conductive member 20a and a second conductive member 20b are formed by e.g. etching. In the conductive member 20, a portion constituting an inclined surface 202 and a lower surface 203 is formed on the same plane. The width (d₁ₐ and d_{1b}) of the portion constituting an inclined surface 202 in the second direction from the first conductive member 20a toward the second conductive member 20b is wider than the width (d₂ₐ and d_{2b}) of the portion constituting a lower surface 203 in the Y direction.

On the upper surface 201 of the conductive member 20, a semiconductor element 10 is placed through a die mounting material (not shown). In the case where the semiconductor element 10 is a light emitting element, the semiconductor element 10 is placed so that the upper end 101 for emitting light is directed to the direction normal to the upper surface 201.

Next, the sealing with a sealing section (step S202) is performed.

As shown in FIG. 13B, a housing case 42 is formed in contact with the upper surface 201. A base section 44 is formed in contact with the lower surface 203. A sealing resin is poured into the opening of the housing case 42 to form a sealing section 40. Here, the sealing section 40 may include phosphor. Thus, part of the conductive member 20 and the semiconductor element 10 are sealed with the sealing section 40.

Next, the bending of the conductive member (step S203) is performed.

As shown in FIG. 13C, the portion of the conductive member 20 exposed from the sealing section 40 is bent to the side opposite to the upper surface 201 of the conductive member 20. Thus, an inclined surface 202 making an acute angle with the upper surface 201, and a lower surface 203 making an obtuse angle with the inclined surface 202 are formed. Furthermore, an inclined surface 204 may be formed on the side opposite to the inclined surface 202 of the lower surface 203.

Also in the fourth embodiment, there is no need to prepare a conductive member 20 having a complex shape at least in the direction perpendicular to the upper surface 201. Furthermore, in the fourth embodiment, by the bending of the conductive member, the inclined surface 202 is formed easily and stably.

### Fifth Embodiment

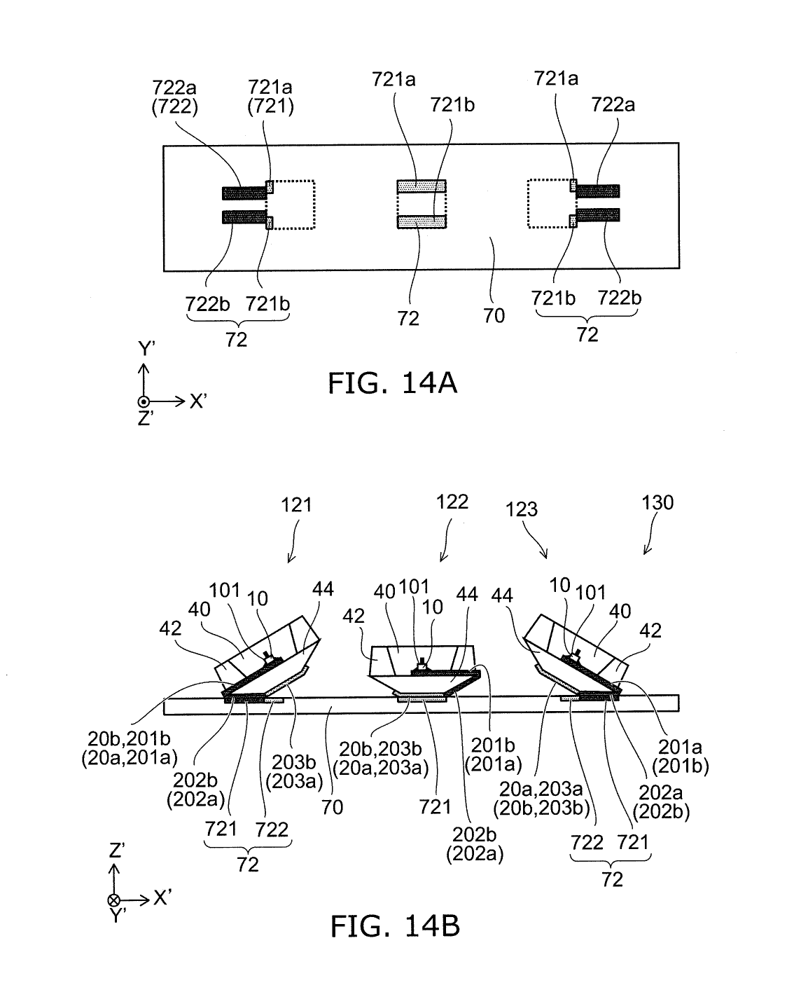

FIGS. 14A and 14B are schematic views illustrating a semiconductor device according to a fifth embodiment.

More specifically, FIG. 14A is a top view of the mounting substrate 70 according to the fifth embodiment. FIG. 14B is a sectional view of the electronic component 130 according to the fifth embodiment.

The fifth embodiment is similar to the third embodiment except that the semiconductor device 120 is mounted on the mounting substrate 70. In the case where the semiconductor element 10 is a light emitting element, the electronic component 130 is e.g. an illumination device.

As shown in FIG. 14A, the mounting substrate 70 includes a plurality of connecting sections 72 on the mounting surface.

In the following description, the direction normal to the mounting surface of the mounting substrate 70 is referred to as +Z′ direction. That is, while the direction normal to the upper surface 201 of the conductive member 20 is referred to as +Z direction, the direction normal to the mounting substrate 70 is distinguished as +Z′ direction. The directions along the mounting surface of the mounting substrate 70 are referred to as +X′ direction and +Y′ direction. The X′ direction, the Y′ direction, and the Z′ direction are orthogonal to each other.

The connecting section 72 includes a conductive material. The connecting section 72 includes at least a first connecting section 721. The connecting section 72 may further include a second connecting section 722.

The first connecting section 721 is connected to part of the lower surface 203 of the conductive member 20 through a solder. Specifically, the first connecting section 721 is connected to part of the lower surface 203 on the inclined surface 202 side.

The second connecting section 722 is continuous with the first connecting section 721. The second connecting section 722 is connected to the inclined surface 202 through a solder. The second connecting section 722 has a larger area than the first connecting section 721.

The first connecting section 721 is provided in a plurality. The second connecting section 722 is also provided in a plurality. The first connecting section 721a and the second connecting section 722a are connected to the first conductive member 20a. The first connecting section 721b and the second connecting section 722b are connected to the second conductive member 20b.

The distance between the first connecting section 721a and the first connecting section 721b is equal to the distance s₁ between the first inclined surface 202a and the second inclined surface 202b on the semiconductor device side. Similarly, the distance between the second connecting section 722a and the second connecting section 722b is equal to the distance s₁ between the first lower surface 203a and the second lower surface 203b. The distance between the first connecting section 721a and the first connecting section 721b is narrower than the distance between the second connecting section 722a and the second connecting section 722b.

In using such a mounting substrate 70, when the semiconductor device is mounted, the connection state of the semiconductor device is transferred by solder stress. Thus, the semiconductor device (first semiconductor device 121 or third semiconductor device 123 described later) is mounted on the mounting substrate 70 in a tilted manner as follows.

As shown in FIG. 14B, the electronic component 130 includes a first semiconductor device 121, a second semiconductor device 122, a third semiconductor device 123, and a mounting substrate 70. The first semiconductor device 121, the second semiconductor device 122, and the third semiconductor device 123 are similar to the semiconductor device 120 in the fourth embodiment. The first semiconductor device 121, the second semiconductor device 122, and the third semiconductor device 123 are mounted on the mounting substrate 70. For instance, the semiconductor element 10 is a light emitting element.

The inclined surface 202 of the first semiconductor device 121 is connected to the second connecting section 722 through a solder. Part of the lower surface 203 of the first semiconductor device 121 is connected to the first connecting section 721 through a solder. Strictly, a solder fillet is formed in contact with the lower surface 203. Thus, the upper end 101 of the semiconductor element 10 in the first semiconductor device 121 is tilted to the −X′ direction with respect to the upper end of the mounting substrate 70.

The lower surface 203 of the second semiconductor device 122 is connected to the first connecting section 721 through a solder. Thus, the upper end 101 of the semiconductor element 10 in the second semiconductor device 122 is directed in the direction (+Z′ direction) perpendicular to the mounting substrate 70. For instance, the second semiconductor device 122 is placed at a position on the +X′ direction side of the first semiconductor device 121.

The inclined surface 202 of the third semiconductor device 123 is connected to the second connecting section 722 through a solder. For instance, the upper end 101 of the semiconductor element 10 in the third semiconductor device 123 is tilted to the opposite side (+X′ direction side) from the first semiconductor device 121. For instance, on the mounting substrate 70, the third semiconductor device 123 is placed on the side opposite to the first semiconductor device 121 of the second semiconductor device 122.

Next, the effect of the fifth embodiment is described.

Here, the case where the semiconductor element 10 is an LED is described. The LED is a light source having high light directivity. This may cause darkening around the direction perpendicular to the upper end 101 of the semiconductor element 10.

In the fifth embodiment, in the case where the semiconductor element 10 is e.g. an LED, the semiconductor device 120 can be mounted on the mounting substrate 70 in a tilted manner. Thus, an illumination device having wide light emitting angle can be provided.

In the foregoing, the fifth embodiment has been described in the case where the electronic component 130 includes a first semiconductor device 121, a second semiconductor device 122, and a third semiconductor device 123. However, the embodiment is not limited thereto. For instance, the electronic component 130 may include two of these semiconductor devices. Furthermore, each of the plurality of semiconductor devices may be directed to various directions. For instance, the plurality of semiconductor devices may be tilted to the same direction. For instance, the upper end of each semiconductor element of the plurality of semiconductor devices may be radially tilted as viewed in the Z′ direction.

### Sixth Embodiment

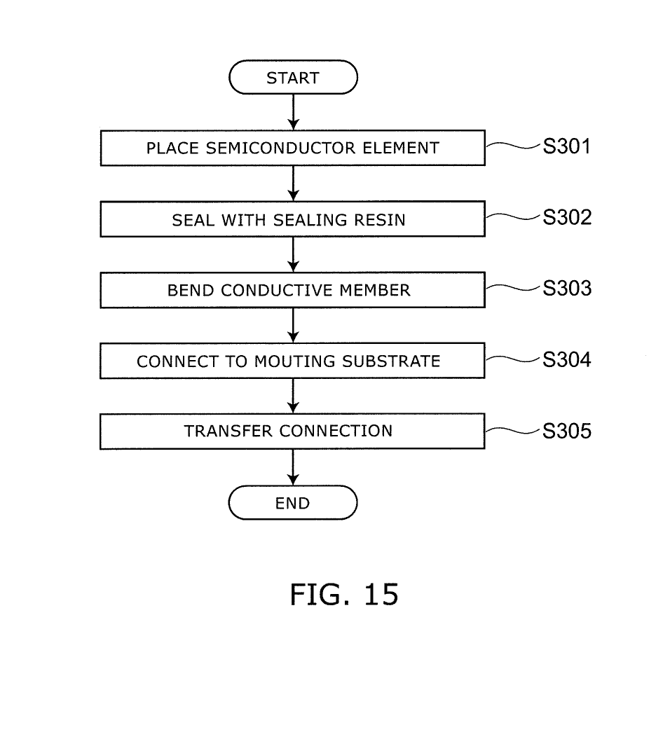

FIG. 15 is a flow chart illustrating a method for manufacturing a semiconductor device according to a sixth embodiment.

The method for manufacturing a semiconductor device according to the sixth embodiment includes the following steps in addition to the same steps (steps S301-S303) as those of the method for manufacturing a semiconductor device according to the fourth embodiment.

In the connecting of the mounting substrate (step S304) after the bending of the conductive member (step S303), part of the lower surface 203 of the conductive member 20 is connected to a first connecting section 721 of a mounting substrate 70 through a solder. The mounting substrate 70 includes, on the mounting surface, a first connecting section 721 including a conductive material, and a second connecting section 722 including a conductive material, being continuous with the first connecting section 721, and having a larger area than the first connecting section 721.

Next, in the transferring of the connection (step S305), the solder is melted. Thus, the connection between the first connecting section 721 and the lower surface 203 is transferred to the connection between the second connecting section 722 and the inclined surface 202.

By the process shown in the above steps S301-S305, the semiconductor device 120 can be mounted on the mounting substrate 70 in a tilted manner.

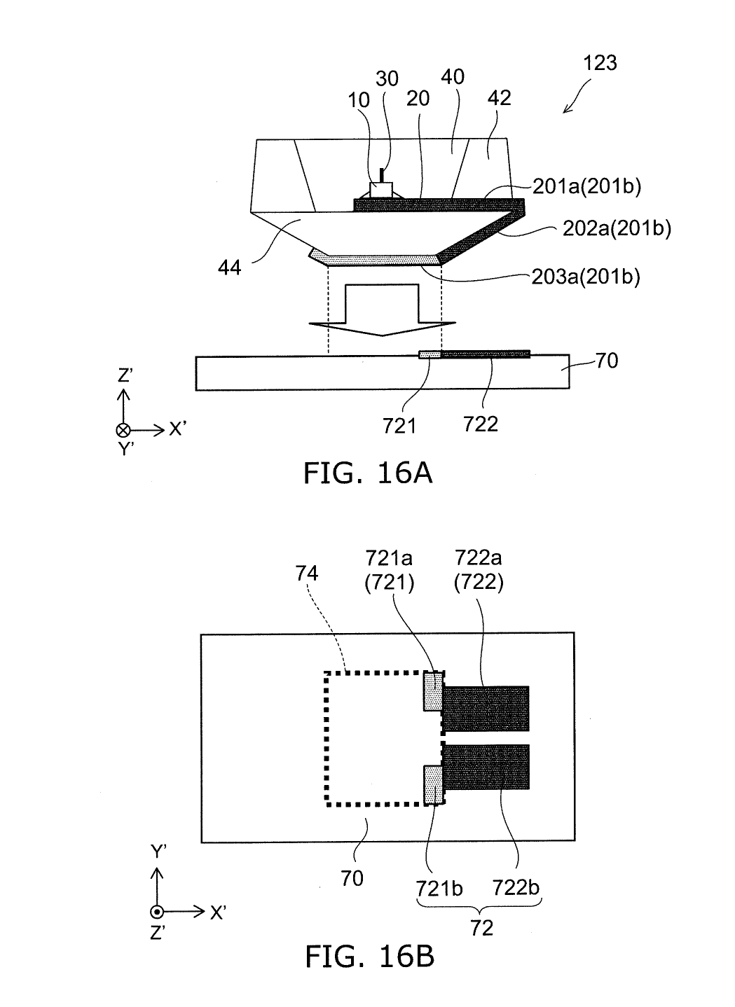

Next, with reference to FIGS. 16A to 19, a more detailed example of the method for manufacturing a semiconductor device according to the sixth embodiment is described.

FIGS. 16A to 19 are schematic sectional views illustrating the method for manufacturing a semiconductor device according to the sixth embodiment.

First, the steps from the placing of a semiconductor element (step S301) to the bending of the conductive member (step S303) are performed. Thus, a semiconductor device shown in FIG. 14C (semiconductor device 120 shown in FIG. 13C) is obtained.

Next, after the bending of the conductive member (step S303), the connecting of a mounting substrate (step S304) is performed.

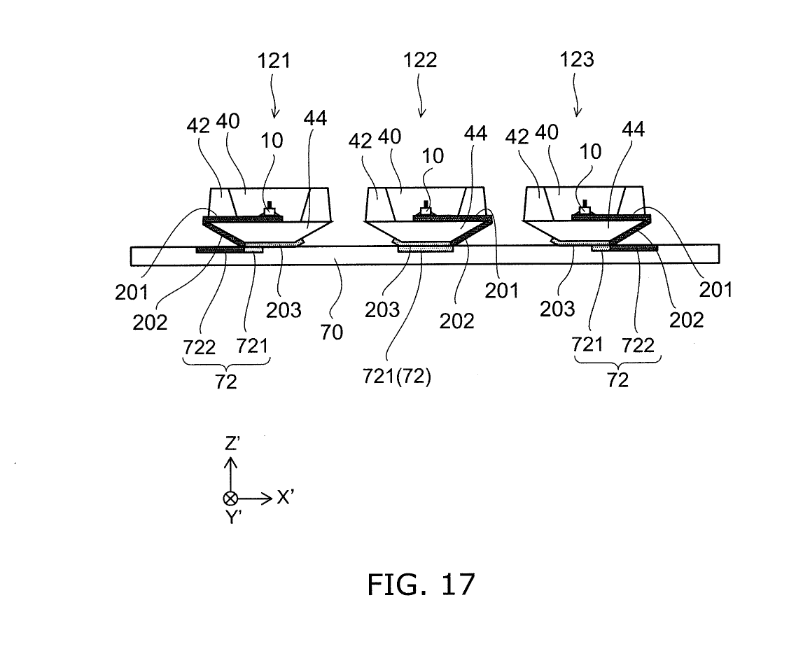

FIG. 16A is a sectional view showing the connecting of a mounting substrate (step S304). FIG. 16B is a top view of the mounting substrate 70 in the connecting of a mounting substrate (step S304). For instance, FIGS. 16A and 16B show the third semiconductor device 123 in FIG. 17 described later.

As shown in FIG. 16B, a mounting substrate 70 is prepared.

The mounting substrate 70 shown in FIG. 16B is similar to e.g. the mounting substrate 70 shown in FIG. 14A.

The mounting substrate 70 includes, on the mounting surface, a connecting section 72 including a conductive material. The connecting section 72 includes a first connecting section 721 and a second connecting section 722. The second connecting section 722 is continuous with the first connecting section 721. The second connecting section 722 has a larger area than the first connecting section 721.

Next, solder is applied to the first connecting section 721 and the second connecting section 722.

As shown in FIG. 16A, the lower surface 203 is placed on the first connecting section 721. Specifically, the inclined surface 202 side of the lower surface 203 is placed on the second connecting section 722 side of the first connecting section 721. In other words, the inclined surface 202 is placed so as to overlap the second connecting section 722 as viewed in the Z′ direction. In addition, part of the lower surface 203 on the inclined surface 202 side is connected to the first connecting section 721 through the solder. Thus, part of the lower surface 203 of the conductive member 20 is temporarily connected.

Here, as shown in FIG. 16B, the third semiconductor device 123 is placed so that the base section 44 overlaps the placement section 74 as viewed in the Z′ direction. As described above, the inclined surface 202 is placed so as to overlap the second connecting section 722 as viewed in the Z direction.

Furthermore, as shown in FIG. 17, a plurality of semiconductor devices may be connected onto the mounting substrate 70. For instance, part of the lower surface 203 of the first semiconductor device 121 is connected to the first connecting section 721. The inclined surface 202 of the first semiconductor device 121 is placed so as to overlap the second connecting section 722 as viewed in the Z′ direction.

The entirety of the lower surface 203 of the second semiconductor device 122 is connected to the first connecting section 721. The connecting section 72 connected to the second semiconductor device 122 does not include the second connecting section 722.

On the mounting substrate 70, the third semiconductor device 123 is placed on the side opposite to the first semiconductor device 121 of the second semiconductor device 122. The first connecting section 721 connected with the third semiconductor device 123 is located on the −X′ direction side of the second connecting section 722.

Next, the transferring of the connection (step S305) is performed. For instance, the mounting substrate 70 with a plurality of semiconductor devices placed thereon is put into a reflow furnace.

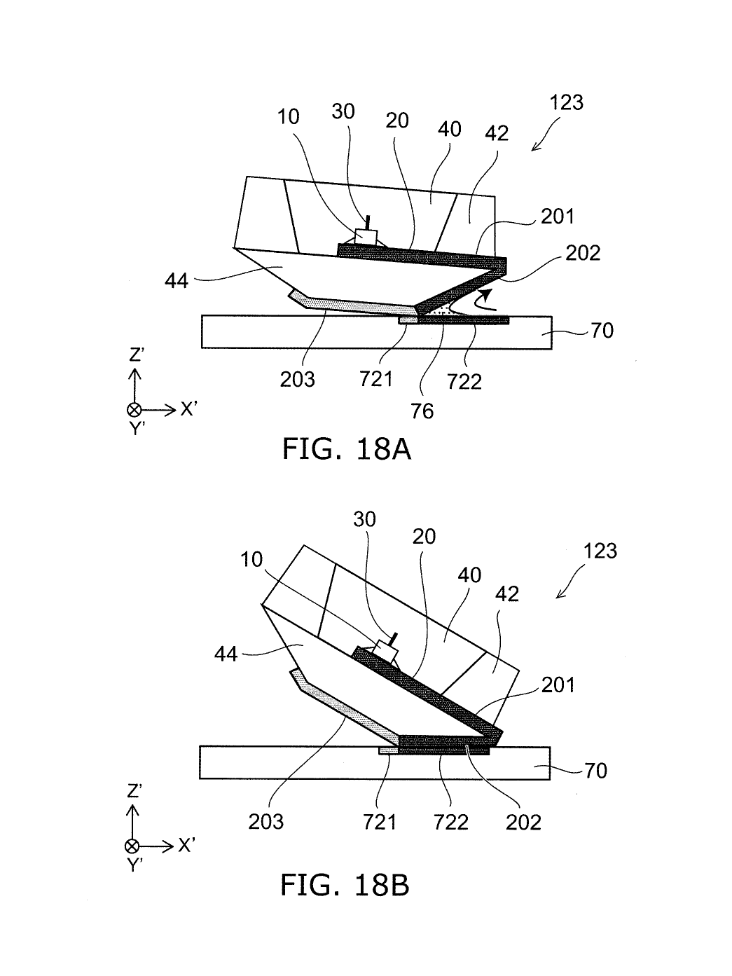

FIGS. 18A and 18B are schematic sectional views illustrating the connection state of the third semiconductor device 123 in FIG. 17.

As shown in FIG. 18A, the solder 76 is melted. The solder 76 on the second connecting section 722 is propagated onto the inclined surface 202 of the third semiconductor device 123. The solder 76 changes so as to reduce surface tension. In other words, the inclined surface 202 is stretched to the side provided with more solder 76. Thus, a stress for bringing the inclined surface 202 close to the second connecting section 722 is applied to the third semiconductor device 123. This stress is referred to as “solder stress”.

As shown in FIG. 18B, the third semiconductor device 123 is tilted to the +X′ direction. Then, the inclined surface 202 is connected to the second connecting section 722. The semiconductor device 123 rises up in the +Z′ direction from the inclined surface 202. Such a phenomenon is often called “Manhattan phenomenon”. Thus, the connection between the semiconductor device 123 and the mounting substrate 70 is transferred from the connection between the first connecting section 721 and the lower surface 203 to the connection between the second connecting section 722 and the inclined surface 202. The term “transferring the connection” used herein refers to changing the connection state.

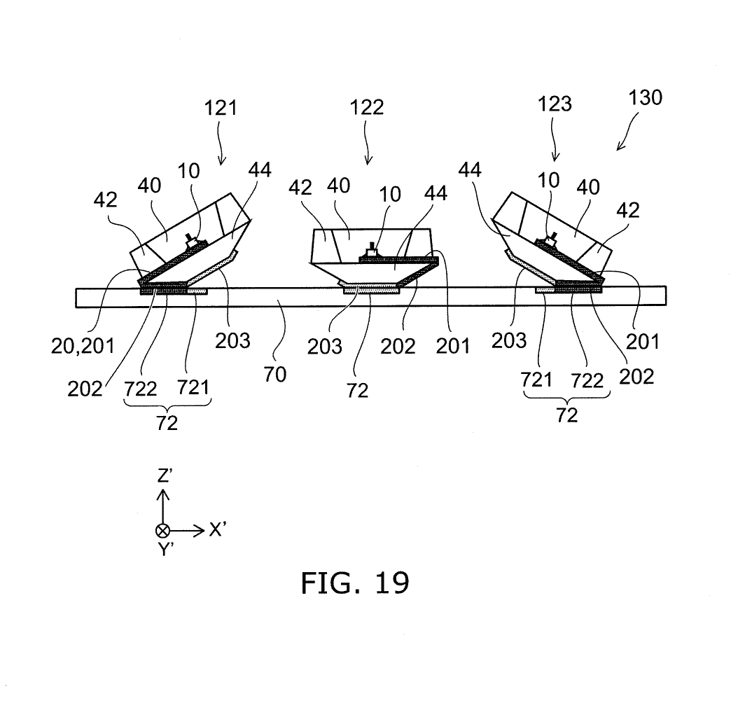

FIG. 19 shows the mounting substrate 70 including a plurality of semiconductor devices shown in FIGS. 18A and 18B after the transferring of the connection (step S305).

As shown in FIG. 19, the inclined surface 202 of the first semiconductor device 121 is connected to the second connecting section 722. The lower surface 203 of the second semiconductor device 122 remains connected to the connecting section 72. The inclined surface 202 of the third semiconductor device 123 is connected to the second connecting section 722.

Next, the effect of the sixth embodiment is described.

Here, the case where the inclined surface 202 is directly connected to the connecting section 72 using a transport apparatus while adjusting the tilt of the semiconductor device is described. In this case, for instance, the semiconductor device 120 is mounted on the mounting substrate 70 as follows.

First, the transport apparatus picks up a semiconductor device from a tray on which a plurality of semiconductor devices are arranged. Next, the semiconductor device is tilted so that the inclined surface of the semiconductor device is directed along the upper surface of the mounting substrate. Next, the semiconductor device in the tilted state is mounted on the mounting substrate.

In this case, a complex transport apparatus may be needed. Furthermore, in the case where the plurality of semiconductor devices are directed in different directions, the mounting condition such as heat treatment temperature may need to be optimized depending on the semiconductor devices with different tilt angles.

In contrast, in the sixth embodiment, the lower surface 203 of the semiconductor device is temporarily connected to the upper surface of the mounting substrate 70. In this state, the solder is melted. The connection between the semiconductor device 123 and the mounting substrate 70 is changed by solder stress to the state in which the second connecting section 722 is in contact with the inclined surface 202. Thus, without application of force from outside, the semiconductor device is tilted with respect to the mounting substrate in a self-aligned manner.

For instance, in the case where a plurality of semiconductor devices are tilted to different directions, a mounting substrate 70 provided with a plurality of connecting sections 72 adapted to desired tilt directions is prepared. Each lower surface of the plurality of semiconductor devices is temporarily connected onto the mounting substrate 70. In this state, the solder is melted. Thus, the tilt of the plurality of semiconductor devices can be changed at once in a self-aligned manner. Furthermore, no complex transport apparatus is needed.

In the case where the semiconductor element 10 is a light emitting element, as described above, a plurality of semiconductor devices directed to various directions can be mounted on the mounting substrate 70 to provide an electronic component 130 having wide directivity.

As described above, the present embodiments provide a semiconductor device and a method for manufacturing the same in which the reliability of connection is improved depending on various mounting configurations.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a conductive member;
a semiconductor element provided on an upper surface of the conductive member; and
a sealing section sealing part of the conductive member and the semiconductor element,
an upper end of the semiconductor element being located above an uppermost portion of the conductive member, and
the conductive member including:
an inclined surface provided on an outside of the sealing section and making an acute angle with the upper surface; and
a lower surface provided on an outside of the sealing section and making an obtuse angle with the inclined surface.

2. The device according to claim 1, wherein
the conductive member is provided integrally from the upper surface to the lower surface, and
the lower surface of the conductive member is a surface on a side opposite to the upper surface of the conductive member.

3. The device according to claim 1, wherein the conductive member includes a protrusion protruding to a first direction along the upper surface and surrounded with the sealing section.

4. The device according to claim 3, wherein
the conductive member includes:
a first portion including the lower surface; and
a second portion provided on the first portion, the second portion including the upper surface, and the second portion protruding from the first portion to the first direction along the upper surface, and
a length along the first direction of the second portion is longer than a length along the first direction of the first portion.

5. The device according to claim 1, wherein the semiconductor element is a light emitting element.

6. The device according to claim 1, wherein the conductive member further includes a bent surface provided between the inclined surface and the lower surface.

7. The device according to claim 6, wherein
the conductive member is provided in a plurality,
a first conductive member of the plurality of conductive members includes a first inclined surface and a first lower surface,
a second conductive member of the plurality of conductive members spaced from the first conductive member in a direction along the upper surface includes a second inclined surface and a second lower surface, and
the first inclined surface and the second inclined surface are juxtaposed along a same outer surface of the sealing section.

8. The device according to claim 1, further comprising:
a mounting substrate including a first connecting section and a second connecting section,
the semiconductor element being provided in a plurality,
the lower surface of a first semiconductor element of the plurality of semiconductor elements being connected to the first connecting section of the mounting substrate, and
the inclined surface of a second semiconductor element of the plurality of semiconductor elements being connected to the second connecting section of the mounting substrate.

9. The device according to claim 8, wherein the semiconductor element is a light emitting element.

10. The device according to claim 8, wherein a distance between the first inclined surface and the second inclined surface is narrower than a distance between the first lower surface and the second lower surface.

11. The device according to claim 10, wherein the semiconductor element is a light emitting element.

12. The device according to claim 5, wherein the sealing section is translucent in a wavelength region of emission light of the light emitting element.

13. A method for manufacturing a semiconductor device, comprising:
placing a semiconductor element on an upper surface of a conductive member;
sealing a region of the conductive member other than a lower surface on a side opposite to the upper surface and the semiconductor element with a sealing section; and
forming an inclined surface on an outside of the sealing section by cutting the conductive member and the sealing section from the lower surface side, the inclined surface making an acute angle with the upper surface.

14. The method according to claim 13, further comprising:
connecting part of the lower surface to a first connecting section of a mounting substrate through a solder, the mounting substrate including, on a mounting surface, the first connecting section including a conductive material, and a second connecting section including a conductive material, being continuous with the first connecting section, and having a larger area than the first connecting section; and
transferring from connection between the first connecting section and the lower surface to connection between the second connecting section and the inclined surface by melting the solder.

15. The method according to claim 13, wherein the semiconductor element is a light emitting element.

16. The method according to claim 13, wherein
the forming an inclined surface includes cutting the conductive member and the sealing section with a cutting blade,
the blade including a cutting portion configured to form the inclined surface.

17. A method for manufacturing a semiconductor device, comprising:
placing a semiconductor element on an upper surface of a conductive member;
sealing part of the conductive member and the semiconductor element with a sealing section; and
forming an inclined surface and a lower surface by bending a portion of the conductive member exposed from the sealing section to a side opposite to the upper surface of the conductive member, the inclined surface making an acute angle with the upper surface, the lower surface making an obtuse angle with the inclined surface.

18. The method according to claim 17, further comprising:
connecting part of the lower surface to a first connecting section of a mounting substrate through a solder, the mounting substrate including, on a mounting surface, the first connecting section including a conductive material, and a second connecting section including a conductive material, the second connecting section being continuous with the first connecting section, and the second connecting section having a larger area than the first connecting section; and
transferring from connection between the first connecting section and the lower surface to connection between the second connecting section and the inclined surface by melting the solder.

19. The method according to claim 17, wherein the semiconductor element is a light emitting element.
